(19) United States
(12) Patent Application Publication
(10) Pub. No.: US 2007/0247194 A1
(43) Pub. Date: Oct. 25, 2007

(54) Output buffer to drive AC-coupled terminated transmission lines

(75) Inventor: Dhruv Jain, Woodland Hills, CA (US)

Correspondence Address: KOPPEL, PATRICK & HEYBL, 555 ST. CHARLES DRIVE, SUITE 107, THOUSAND OAKS, CA, 91360, US

(73) Assignee: INPHI CORPORATION

(21) Appl. No.: 11/410,680

(22) Filed: Apr. 24, 2006

(51) Int. Cl. H03K 19/094

(52) U.S. Cl. 326/87

(57) ABSTRACT

An output buffer for driving an AC-coupled resistively terminated transmission line comprises at least first and second drive circuits coupled to an input signal and providing respective drive signals that transition in response to respective transitions of the input signal. The buffer is arranged such that, in response to a given input signal transition, the second drive signal transitions a predetermined amount of time after the first drive signal. The first and second drive signals are summed together to provide the buffer's output signal. The drive circuits are arranged such that the output signal has a first slew rate prior to the transition of the second drive signal, and a second, faster slew rate during the transition of the second drive signal, such that the slew rates reduce ringing that might otherwise occur on the transmission line.

### BACKGROUND OF THE INVENTION

1. Field of the Invention

This invention relates to the field of output buffers, and particularly to output buffers used to drive AC-coupled terminated transmission lines.

2. Description of the Related Art

There are many applications in which output buffers drive respective transmission lines to convey data to one or more devices connected to the transmission lines. In such applications, it is important that the integrity of the data on the transmission lines be maintained, so that it can be accurately detected by the receiving devices.

One such application is a random access memory (RAM) system. Dual-Inline Memory Modules (DIMMs) are the industry-standard platform on which RAM is provided for digital computers. Each DIMM is a printed-circuit board which contains a number of individual RAM integrated circuits (ICs) or “chips.” DIMMs typically contain address and/or control registers which distribute data bits to each of the DIMM's RAM chips via transmission lines driven by respective output buffers.

A typical DIMM arrangement is shown in FIG. 1. An output buffer 10 includes a drive circuit 12 which drives a transmission line 14. The DIMM includes a number of RAM chips 16; dynamic RAM (DRAM) chips are shown in FIG. 1, though a DIMM can include other RAM types as well. Transmission line 14 is routed to an address or control input on each RAM chip. DIMMs are provided in a variety of configurations. Each DIMM type has an associated set of specifications, promulgated by the industry-supported JEDEC Solid State Technology Association international standards body, which govern the DIMM's configuration and operation. For some DIMM types, the specifications require that each transmission line be “terminated”; i.e., that a termination resistor Rₜ be connected between each transmission line and a fixed voltage, denoted in FIG. 1 as V+. Termination resistors serve to improve the signal quality on lines such as transmission line 14.

The use of termination resistors in this way can have an undesirable side effect, however, in that they tend to increase the DIMM's power consumption. For example, assuming that the output impedance of drive circuit 12 is ˜0Ω, V+ is 0.75 volts, and Rₜ is 30Ω, then the static power dissipation P_{diss} associated with one transmission line is: P_{diss}=(V+)²/Rₜ=18.75 mW/transmission line. There are typically 20-30 transmission lines on a DIMM, such that power dissipation due to Rₜ can be 500 mW or more.

### SUMMARY OF THE INVENTION

An output buffer for driving AC-coupled resistively terminated transmission lines is presented which overcomes the problems noted above, by reducing power dissipation that would otherwise arise due to the termination resistor, while still maintaining the integrity of data being conveyed.

A capacitor is connected in series with each termination resistor such that each transmission line is AC-coupled to its termination voltage, thereby blocking DC current which would otherwise be dissipated in the resistor. Then, an output buffer in accordance with the present invention is used to drive each AC-coupled resistively terminated transmission line, with the buffer arranged to ensure the integrity of the data conveyed.

The present output buffer comprises at least two drive circuits coupled to an input signal; for purposes of illustration, first and second drive circuits are assumed, which provide respective drive signals that transition between ‘low’ and ‘high’ states in response to respective transitions of the input signal. The buffer is arranged such that, in response to a given input signal transition, the second drive signal transitions a predetermined amount of time after the first drive signal. The first and second drive signals are summed together to provide the buffer's output signal.

The first and second drive circuits are arranged such that, during output signal transitions of at least one polarity, the output signal has a first slew rate prior to the transition of the second drive signal, and a second, faster slew rate during the transition of the second drive signal. The drive circuits are preferably arranged such that the output signal's first and second slew rates act to reduce ringing on the transmission line in comparison with an output signal which transitions exclusively at a slew rate greater than the first slew rate. The delay between the first and second drive signal transitions and the output strengths of the respective drive signals may be made adjustable, such that the shape of the output signal waveform can be tailored as needed for a particular application.

As noted above, the present output buffer can include more than two drive circuits, each of which contributes to the buffer's output signal transitions. As above, the delays and output strengths associated with the respective drive signals can be made adjustable to further shape the output signal waveform.

Further features and advantages of the invention will be apparent to those skilled in the art from the following detailed description, taken together with the accompanying drawings.

### BRIEF DESCRIPTION OF THE DRAWINGS

FIG. 1 is a block diagram of a known memory system configuration.

FIG. 2 is a block diagram of an output buffer per the present invention, as it might be employed in a memory system application.

FIG. 3 is a timing diagram for the output buffer of FIG. 2.

FIG. 4 is a schematic diagram of one possible implementation of an output buffer per the present invention.

FIG. 5 is a schematic diagram of one possible implementation of a delay circuit as might be used in an output buffer per the present invention.

FIG. 6 is a block diagram of a drive circuit with tunable output impedance as might be used in an output buffer per the present invention.

FIG. 7a is a block diagram of one possible embodiment of an output buffer per the present invention which has more than two drive circuits.

FIG. 7b is a block diagram of another possible embodiment of an output buffer per the present invention which has more than two drive circuits.

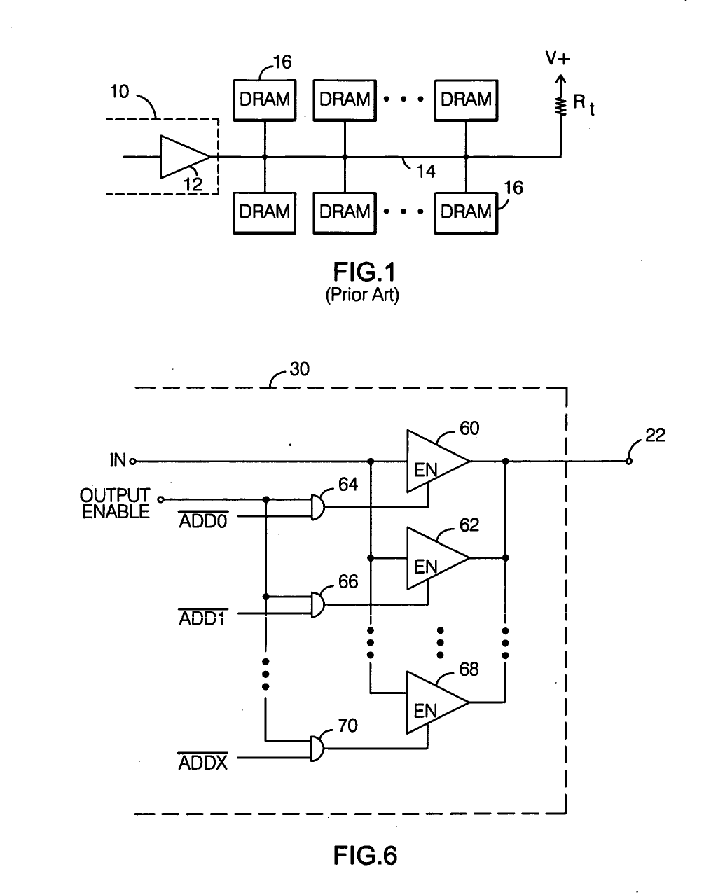

### DETAILED DESCRIPTION OF THE INVENTION

The present output buffer is intended for use driving AC-coupled resistively terminated transmission lines, particularly when power consumption is a concern. The invention employs a capacitor connected in series with each lines' termination resistor Rₜ, to reduce power consumption that might otherwise occur due to the resistor. AC-coupling the transmission line to termination voltage V+ in this way also eliminates restrictions that may be imposed on V+.

The invention also includes an output buffer having at least two drive circuits, the outputs of which are summed to provide the buffer's output signal. For purposes of illustration, an output buffer with first and second drive circuits is described below, followed by a discussion of buffers with more than two drive circuits. The first drive circuit is coupled to an input signal, and provides a first drive signal which transitions between ‘low’ and ‘high’ states in response to respective transitions of the input signal. The second drive circuit is also coupled to the input signal, and provides a second drive signal which transitions between ‘low’ and ‘high’ states in response to respective transitions of the input signal. The buffer is arranged such that, in response to a given input signal transition, the second drive signal transitions a predetermined amount of time after the first drive signal. The first and second drive signals are summed together to provide the buffer's output signal, which is intended for driving an AC-coupled resistively terminated transmission line.

The first and second drive circuits are arranged such that, during output signal transitions of at least one polarity, the output signal has a first slew rate prior to the transition of the second drive signal, and a second, faster slew rate during the transition of the second drive signal. The drive circuits are preferably arranged such that their respective slew rates produce an output signal waveform which maintains the integrity of the data being conveyed on the transmission line. For example, the use of first and second slew rates as described herein can reduce the amplitude and duration of ringing on the driven transmission line, in comparison with an output signal which transitions exclusively at a slew rate greater than the first slew rate.

Though the present buffer is generally applicable to any AC-coupled terminated transmission line application, a primary application is in a memory system, in which each buffer drives a terminated address or control line routed to multiple. RAM chips populating a DIMM memory module. For example, for DIMMs in compliance with the DDR3 specifications promulgated by JEDEC, each address and control line is routed to multiple DRAM chips on the DIMM, and each line is terminated with a termination resistor having a resistance Rₜ. For purposes of illustration, this application is described throughout, though the invention is in no way limited to use with DIMMs.

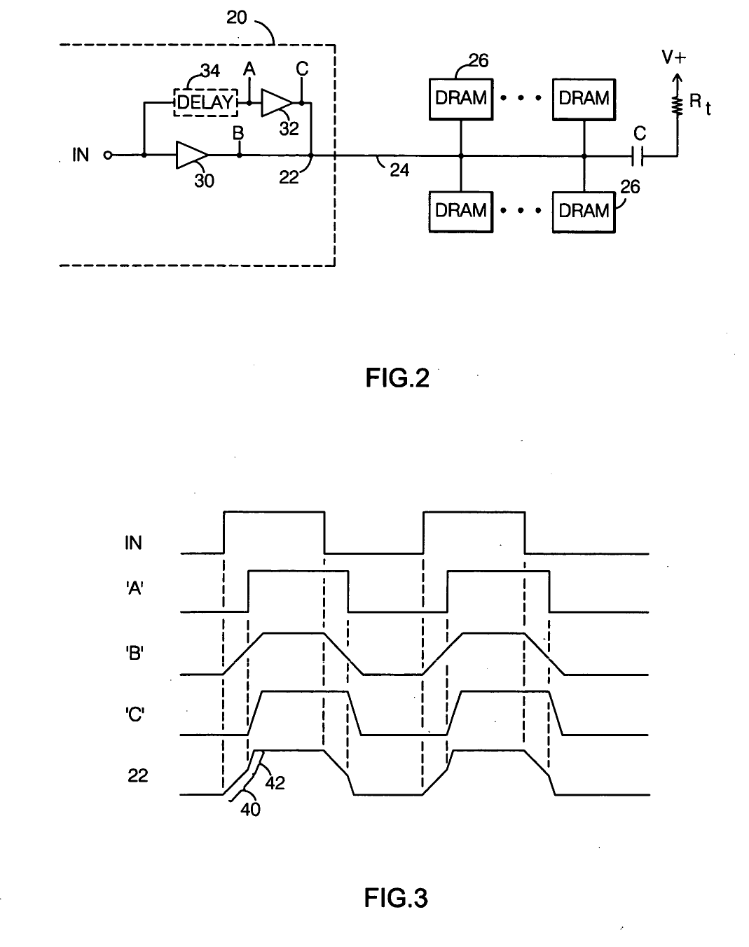

A block diagram of an output buffer per the present invention, as it might be employed in a memory system application, is shown in FIG. 2. An output buffer 20 produces an output signal 22 connected to drive a transmission line 24, which is terminated with a termination resistor Rₜ. In a DIMM application as described above, output buffer 20 conveys data bits to an input of each RAM chip 26 on the DIMM via transmission line 24.

When terminated in accordance with JEDEC requirements (i.e., without AC-coupling), power is continuously dissipated in termination resistor Rₜ, even when output buffer 20 is not switching the state of transmission line 24. As noted above, under these conditions, static power dissipation P_{diss} due to Rₜ is given by: P_{diss}=(V+)²/Rₜ=18.75 mW/signal line, assuming Rₜ=30Ω and V+=0.75 volts. As noted above, a capacitor C is connected in series with Rₜ, to reduce P_{diss} (note that C can be connected on either side of Rₜ; it only needs to block buffer 20 from seeing V+) . With transmission line 24 AC-coupled in this way, DC current which would otherwise be dissipated in the resistor is blocked; power is only dissipated in Rₜ when output signal 22 transitions between ‘high’ and ‘low’ states.

However, though capacitor C acts to reduce P_{diss}, it may degrade the integrity of the data being conveyed on transmission line 24. The invention overcomes this problem with the use of an output buffer which produces a drive signal designed to maintain the integrity of data so conveyed.

The output buffer 20 includes a first drive circuit 30 and a second drive circuit 32. As noted above, the drive circuits' inputs are both coupled to an input signal IN, and their outputs are connected together to provide output signal 22, which is connected to drive AC-coupled resistively terminated transmission line 24. Drive circuits 30 and 32 produce respective drive signals (identified as signals ‘B’ and ‘C’, respectively) which transition between ‘low’ and ‘high’ states in response to respective transitions of input signal IN.

Note that, with the outputs of drive circuits 30 and 32 tied together, signals ‘B’ and ‘C’ are actually the same signal and must transition as one. As used herein, drive signal ‘B’ refers to the component of output signal 22 originating from drive circuit 30, and drive signal ‘C’ refers to the component of output signal 22 originating from drive circuit 32.

Second drive circuit 32 is arranged such that, in response to a given input signal transition, its drive signal ‘C’ transitions a predetermined amount of time after drive signal ‘B’; this transition delay is represented in FIG. 2 with a “DELAY” circuit 34. The drive circuits are further arranged such that, during output signal transitions of at least one polarity, the combined output signal 22 has a first slew rate prior to the transition of drive signal ‘C’, and a second slew rate during the transition of drive signal ‘C’.

The operation of buffer 20 is illustrated in the timing diagram shown in FIG. 3. Input signal IN toggles between ‘high’ and ‘low’ states as needed to convey a particular data pattern on transmission line 24; signal ‘A’ shows IN after it has been delayed by delay circuit 34. As noted above, output signal 22 is created by summing together the outputs of drive circuits 30 and 32. The signal labeled as ‘B’ in FIG. 3 shows the contribution to output signal 22 provided by drive circuit 30, and the signal labeled ‘C’ in FIG. 3 shows the contribution provided by drive circuit 32. The resulting output signal (22) has a first slew rate 40 prior to the transition of drive signal ‘C’, and a second slew rate 42 during the transition of drive signal ‘C’, with the first slew rate being less than the second slew rate. The first slew rate is preferably arranged to be fast enough such that it is largely coupled through capacitor C to termination voltage V+, but not so fast as to induce ringing on transmission line 24. Then, with the transition of drive signal ‘C’, output signal 22 is preferably rapidly pulled up towards the positive supply rail. The ideal shape of the output signal waveform and the size of capacitor C vary depending on the particular application, with the loading presented by the devices being driven (here, DRAM chips 26) being the primary factor, in addition to transmission line impedance, termination resistance and data rate. Note that, it is preferable but not necessary that the transition rate of drive signal ‘C’ be greater than that of drive signal ‘B’. Even if ‘C’ were not faster than ‘B’, second slew rate 42 would still be faster than first slew rate 40, as both drive circuits are pulling in parallel on output signal 22 during this period.

In the timing diagram of FIG. 3, both low-to-high and high-to-low transitions of the output signal are shown as being shaped by the first and second drive circuits. Note that a buffer per the present invention could be arranged to shape only rising edges, only falling edges, or both, as required by a particular application.

Output buffer 20 can be arranged such that one or more aspects of the waveform of output signal 22 are adjustable: in particular, the delay between the ‘B’ and ‘C’ transitions and/or the strength output signal 22 can be made tunable. These options are discussed in more detail below.

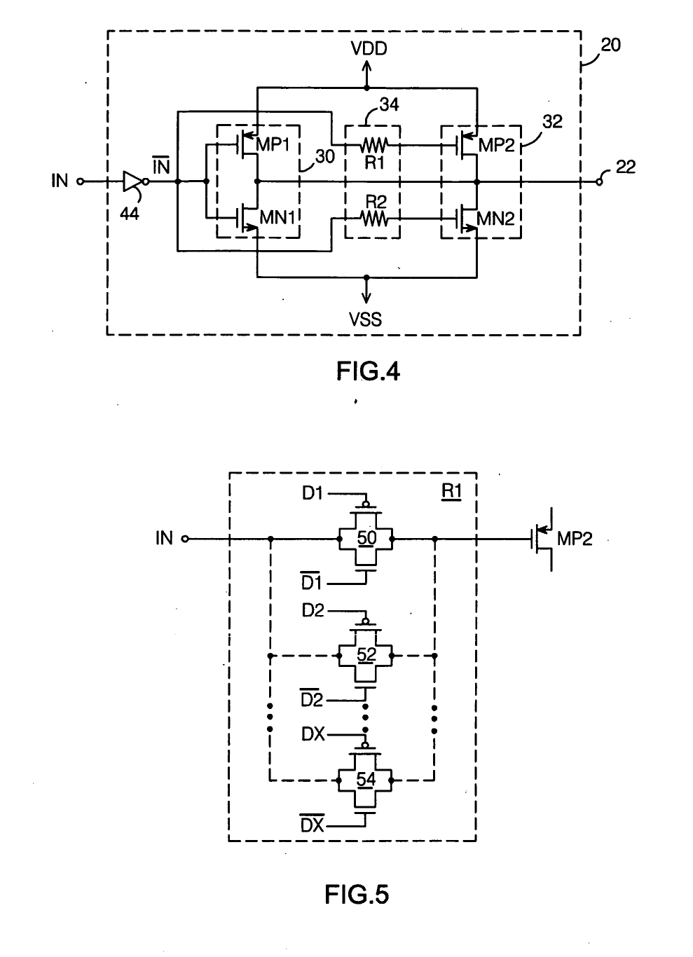

An output buffer capable of producing an output signal as described herein could be implemented in many different ways. One possible implementation of an output buffer in accordance with the present invention is shown in FIG. 4. First drive circuit 30 is implemented with an inverter circuit comprising FETs MP1 and MN1 connected between positive and negative supply voltages VDD and VSS. The gates of MP1 and MN1 are coupled to IN (via an inverter 44 which produces an output I̅N̅ in this exemplary embodiment), and their common drains are connected together to provide the first drive signal component of output signal 22. Second drive circuit 32 is implemented with an inverter circuit comprising FETs MP2 and MN2 connected between VDD and VSS, with their gates coupled to I̅N̅ and their common drains connected together to provide the second drive signal component of output signal 22. Here, delay circuit 34 is implemented with a pair of resistances R1 and R2, which are connected in series between I̅N̅ and the gates of MP2 and MN2, respectively. Resistances R1 and R2 form R-C networks with the inherent capacitances of MP2 and MN2, respectively, which serve to delay the application of input signal IN to the MP2/MN2 gates—and thus the transition of their common drains. Note that, while the use of inverter 44 makes the buffer of FIG. 4 operate in accordance with the timing diagram of FIG. 3, its use is incidental.

Note that the delay in the transition of the second drive signal can be implemented in many ways; the method shown in FIG. 4 is merely exemplary. For example, rather than rely on the inherent capacitances of MP2 and MN2, discrete capacitors might be used. Resistive elements for delays can be implemented using discrete resistors, transistors, etc. Delay circuit 34 might also be implemented as a discrete circuit, using, for example, a flip-flop, shift register, inverter string, logic gate chains or other transistor implementations of delay elements. Alternatively, the desired delay can be designed into second drive circuit 32.

When implemented as shown in FIG. 4, it may be desirable to make resistances R1 and R2 variable, thereby enabling the delay between the ‘B’ and ‘C’ transitions to be adjusted. One way in which R1 and R2 can be made variable is shown in FIG. 5, in which one or more pass gates 50, 52, 54 are used to create the desired resistance (R1 in the example shown). The pass gates are connected in parallel, with each pass gate input connected to IN, and each pass gate output connected together and to the gate of MP2. When so arranged, the overall resistance varies with the number of ‘on’ pass gates, with overall resistance decreasing as more pass gates are turned on. Each pass gate is controlled with a respective pair of control signals (D1, D̅1̅; D2, D̅2̅; . . . ; DX, D̅X̅). Additional resistance values could be achieved by connecting additional pass gates in parallel with pass gates 50, 52, 54 and providing control signals to turn them on or off as needed.

Another way in which the waveform of output signal 22 might be adjusted is to make the output impedance of one or both of drive circuits 30 and 32 tunable, as both the slew rate and drive strength of a drive circuit's drive signal vary with its output impedance. The output impedance of a drive circuit may be made variable by a wide variety of means; one exemplary implementation is shown in FIG. 6. Here, drive circuit 30 contains at least two constituent drivers (60, 62) connected in parallel. Each driver receives the same input signal (IN), and their outputs are tied together to provide the first drive signal component of output signal 22. The drive circuits are preferably activated in response to an “enable” signal (EN). In this approach, the overall output impedance for drive circuit 30 varies with the number of active drivers connected in parallel, with output impedance decreasing as more drivers are activated.

For the exemplary embodiment shown in FIG. 6, the output impedance is controlled by enabling a desired number of drivers. Drive circuit 30 would typically receive an “output enable” signal, which is logically combined with respective independent control signals ( A̅D̅D̅0̅, A̅D̅D̅1̅)—here, using AND gates 64 and 66—to provide enable signals to respective drivers. Additional resolution for setting the output impedance of drive circuit 30 could be obtained by connecting additional drivers (68) in parallel with drivers 60 and 62 and providing control signals ( A̅D̅D̅X̅ via AND gate 70) to their enable inputs as needed to achieve a desired output impedance. As the number of active parallel drivers is increased, the output impedance decreases. A tri-state mode could be enabled by setting the “output enable” signal so that all the drivers are off. Additional methods for providing a tunable output impedance are discussed, for example, in co-pending patent application Ser. No. 11/376,593, which is assigned to the present assignee.

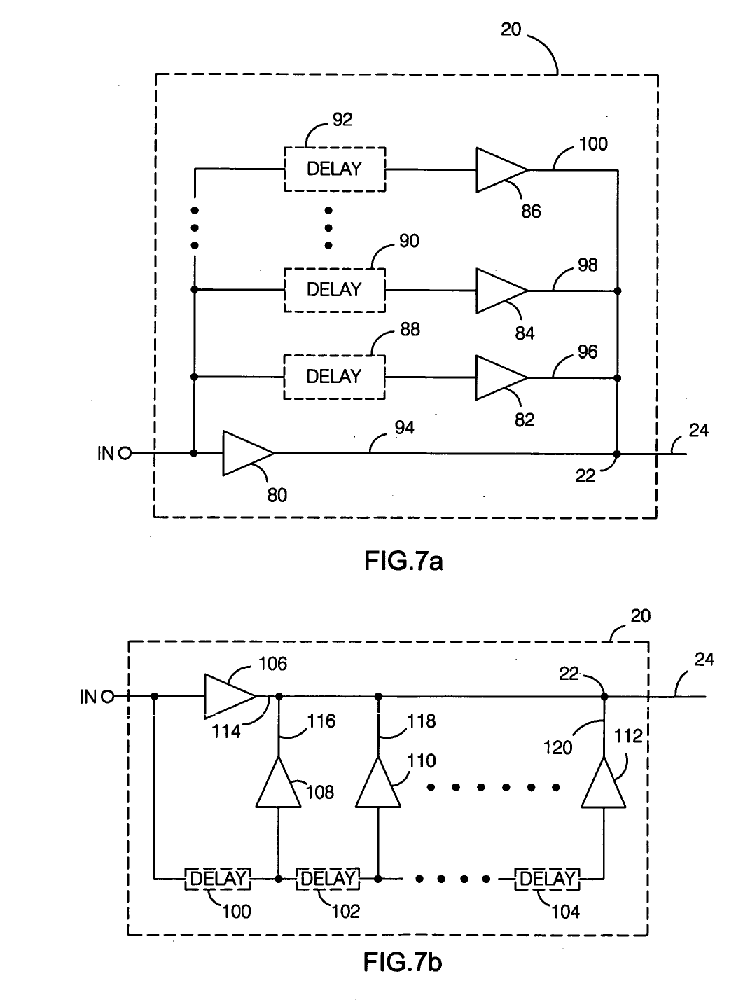

As noted above, an output buffer in accordance with the present invention can have more than two drive circuits. Such a buffer could be implemented in many different ways; one possible embodiment is illustrated in FIG. 7a. Here, a first drive circuit 80 is coupled to IN, and two or more additional drive circuits 82, 84, 86 are also coupled to IN via respective delay circuits 88, 90, 92. As before, the drive circuits produce respective drive signals (94, 96, 98, 100), all of which are summed to provide output signal 22, with the drive signals produced by circuits 82, 84 and 86 transitioning after that of circuit 80. The delays circuits' respective delay times, and the drive circuits' respective output impedances, can each be made different and/or adjustable as discussed above. In this way, transitions of the resulting output signal could potentially have as many slew rate components as there are drive circuits. However, regardless of the number of drive circuits, the buffer is arranged such that a transition of output signal 22 has a first slew rate prior to the transition of drive signals 96, 98 100, and one or more slew rates during the transitions of drive signals 96, 98 100, with the output signal's first slew rate being less than the subsequent slew rates.

Another possible embodiment of an output buffer having more than two drive circuits is shown in FIG. 7b. Here, delay circuits 100, 102, 104 form a delay line coupled at one end to IN, and the inputs to the drive circuits 106, 108, 110, 112 are connected to different points along the line. As before, the drive circuits produce respective drive signals (114, 116, 118, 120), all of which are summed to provide output signal 22. The delay line arrangement ensures that the drive signals transition in a known sequence. The delays circuits' respective delay times, and the drive circuits' respective output impedances, can each be made different and/or adjustable as discussed above. In this way, transitions of the resulting output signal could potentially have as many slew rate components as there are drive circuits.

Note that the circuits and methods shown in FIGS. 2 and 4-7b for providing an output signal waveform suitable for driving AC-coupled resistively terminated transmission lines as described herein are merely exemplary. There are myriad ways in which these circuits could be realized, and many possible control schemes for operating them. It is only essential that a transmission line being driven include a capacitor in series with a termination resistor, and that the present output buffer include first and second drive circuits arranged such that, in response to a given input signal transition, the second drive signal transitions a predetermined amount of time after the first drive signal. The first and second drive signals are summed together to provide the buffer's output signal, with the output signal having a first slew rate prior to the transition of the second drive signal, and a second, faster slew rate during the transition of the second drive signal.

Note that, though the schematics contained herein depict the use of field-effect transistors (FETs), bipolar transistors or other state-of-the-art current switching integrated circuit devices could also be used.

While particular embodiments of the invention have been shown and described, numerous variations and alternate embodiments will occur to those skilled in the art. Accordingly, it is intended that the invention be limited only in terms of the appended claims.

I claim:

1. An output buffer adapted for driving an AC-coupled resistively terminated transmission line, said output buffer arranged to provide an output signal which transitions between ‘low’ and ‘high’ states to convey data bits via said transmission line, said output buffer comprising:
a first drive circuit having an input which is coupled to an input signal and which provides a first drive signal which transitions between ‘low’ and ‘high’ states in response to respective transitions of said input signal; and
at least one additional drive circuit, each of which has an input coupled to said input signal and provides an additional drive signal which transitions between ‘low’ and ‘high’ states in response to respective transitions of said input signal;
said buffer arranged such that, in response to a given input signal transition, said additional drive signals transition a predetermined amount of time after said first drive signal, said first and additional drive signals summed together to provide said output signal;
said first and additional drive circuits arranged such that, during output signal transitions of at least one polarity, said output signal has a first slew rate prior to the transitions of said additional drive signals, and one or more subsequent slew rates during the transitions of said additional drive signals, said first slew rate being less than said subsequent slew rates.

2. The output buffer of claim 1, wherein said additional drive circuits are arranged such that said predetermined amount of time can be varied for each of said additional drive signals in response to one or more control signals.

3. The output buffer of claim 1, wherein each of said drive circuits has an associated output impedance, at least one of said drive circuits including a means for varying its output impedance in response to at least one control signal.

4. An output buffer adapted for driving an AC-coupled resistively terminated transmission line, said output buffer arranged to provide an output signal which transitions between ‘low’ and ‘high’ states to convey data bits via said transmission line, said output buffer comprising:
a first drive circuit having an input which is coupled to an input signal and which provides a first drive signal which transitions between ‘low’ and ‘high’ states in response to respective transitions of said input signal;
at least one additional drive circuit, each of which has an input coupled to said input signal and provides an additional drive signal which transitions between ‘low’ and ‘high’ states in response to respective transitions of said input signal, said drive signals summed together to provide said output signal; and
one or more delay circuits, respective ones of which are connected in series between said input signal and a respective one of said additional drive circuits such that each of said additional drive signals transitions after said first drive signal by an amount of time determined by the delay circuit connected in series with said drive circuit, such that, during output signal transitions of at least one polarity, said output signal has a first slew rate prior to the transitions of said additional drive signals, and one or more subsequent slew rates during the transitions of said additional drive signals, said first slew rate being less than said subsequent slew rates.

5. An output buffer adapted for driving an AC-coupled resistively terminated transmission line, said output buffer arranged to provide an output signal which transitions between ‘low’ and ‘high’ states to convey data bits via said transmission line, said output buffer comprising:
a first drive circuit having an input which is coupled to an input signal and which provides a first drive signal which transitions between ‘low’ and ‘high’ states in response to respective transitions of said input signal;
at least one additional drive circuit, each of which has an input coupled to said input signal and provides an additional drive signal which transitions between ‘low’ and ‘high’ states in response to respective transitions of said input signal, said drive signals summed together to provide said output signal; and
two or more delay circuits connected in series to form a delay line which is coupled at its input to said input signal, said additional drive circuits' inputs connected to respective points along said delay line such that each of said additional drive signals transitions in sequence after said first drive signal by an amount of time determined by the delay circuits connected between said drive circuit's input and said input signal, such that, during output signal transitions of at least one polarity, said output signal has a first slew rate prior to the transitions of said additional drive signals, and one or more subsequent slew rates during the transitions of said additional drive signals, said first slew rate being less than said subsequent slew rates.

6. An output buffer adapted for driving an AC-coupled resistively terminated transmission line, said output buffer arranged to provide an output signal which transitions between ‘low’ and ‘high’ states to convey data bits via said transmission line, said output buffer comprising at least two drive circuits, said at least two drive circuits comprising:
a first drive circuit having an input which is coupled to an input signal and which provides a first drive signal which transitions between ‘low’ and ‘high’ states in response to respective transitions of said input signal; and
a second drive circuit having an input which is coupled to said input signal and which provides a second drive signal which transitions between ‘low’ and ‘high’ states in response to respective transitions of said input signal, said buffer arranged such that, in response to a given input signal transition, said second drive signal transitions a predetermined amount of time after said first drive signal, said first and second drive signals summed together to provide said output signal;
said first and second drive circuits arranged such that, during output signal transitions of at least one polarity, said output signal has a first slew rate prior to the transition of said second drive signal, and a second slew rate during the transition of said second drive signal, said first slew rate being less than said second slew rate.

7. The output buffer of claim 6, wherein said first and second drive circuits are arranged such that said output signal's first and second slew rates reduce ringing on said transmission line in comparison with an output signal which transitions exclusively at a slew rate greater than said first slew rate.

8. The output buffer of claim 6, wherein:
said first drive circuit comprises:
first and second complementary transistors arranged to form a first inverter, said input signal connected to the input of said first inverter and the output of said first inverter providing said first drive signal; and
said second drive circuit comprises:
third and fourth complementary transistors arranged to form a second inverter, said input signal coupled to the input of said second inverter and the output of said second inverter providing said second drive signal; and
a delay circuit connected in series between said input signal and said third and fourth complementary transistors, respectively, such that said second drive signal transitions a predetermined amount of time after said first drive signal.

9. The output buffer of claim 8, wherein said delay circuit comprises first and second resistances connected in series between said input signal and said third and fourth complementary transistors, respectively.

10. The output buffer of claim 9, wherein said first and second resistances form respective R-C networks with the inherent capacitances of said third and fourth complementary transistors.

11. The output buffer of claim 9, wherein the value of at least one of said resistances varies in response to at least one control signal.

12. The output buffer of claim 9, wherein said resistances comprise respective pass gates.

13. The output buffer of claim 9, wherein each of said resistances comprises at least two pass gates connected in parallel, said pass gates turned on and off in response to respective control signals to provide desired resistance values and thereby set said predetermined amount of time.

14. The output buffer of claim 6, wherein each of said first and second drive circuits has an associated output impedance, at least one of said first and second drive circuits including a means for varying its output impedance in response to at least one control signal.

15. The output buffer of claim 14, wherein each of said drive circuits which include said means for varying said output impedance comprises multiple drivers connected in parallel, the outputs of said parallel-connected drivers summed to produce the drive signal provided by said drive circuit, said parallel-connected drivers enabled and disabled in response to respective control signals to present a desired output impedance.

16. The output buffer of claim 6, wherein said output buffer is contained within an address register which contains a plurality of said output buffers, said buffers arranged to provide respective output signals which drive respective AC-coupled resistively terminated transmission lines, at least some of which are connected to the address or control inputs of respective random-access memory (RAM) chips residing on a Dual-Inline Memory Module (DIMM).

17. The output buffer of claim 16, wherein said DIMM is part of a DDR3 memory system, the transmission lines of which are terminated in accordance with applicable JEDEC specifications.

18. The output buffer of claim 6, further comprising an AC-coupled resistively terminated transmission line which is driven by said output signal.

19. The output buffer of claim 6, wherein said predetermined amount of time varies in response to at least one control signal.

20. An output buffer adapted for driving an AC-coupled resistively terminated transmission line, said output buffer arranged to provide an output signal which transitions between ‘low’ and ‘high’ states to convey data bits via said transmission line, said output buffer comprising:
a first drive circuit having an input which is coupled to an input signal and which provides a first drive signal which transitions between ‘low’ and ‘high’ states in response to respective transitions of said input signal;
a second drive circuit having an input which is coupled to said input signal and which provides a second drive signal which transitions between ‘low’ and ‘high’ states in response to respective transitions of said input signal; and
a delay circuit connected between said input signal and the input of said second drive circuit, said delay circuit arranged such that said second drive signal transitions a predetermined amount of time after said first drive signal;
said first and second drive signals summed together to provide said output signal;
said first and second drive circuits arranged such that, during output signal transitions of at least one polarity, said output signal has a first slew rate prior to the transition of said second drive signal, and a second slew rate during the transition of said second drive signal, said first slew rate being less than said second slew rate such that said output signal's first and second slew rates reduce ringing on said transmission line in comparison with an output signal which transitions exclusively at a slew rate greater than said first slew rate.

21. The output buffer of claim 20, wherein said delay circuit comprises at least one resistance which forms an R-C network with the capacitance of said second drive circuit to impose said delay.

22. The output buffer of claim 21, wherein the value of said at least one resistance varies in response to at least one control signal.

23. The output buffer of claim 20, wherein each of said first and second drive circuits has an associated output impedance, at least one of said first and second drive circuits including a means for varying its output impedance in response to at least one control signal.

24. A memory system, comprising:
a plurality of transmission lines which route signals from respective output buffers to the address or control inputs of a plurality of random-access memory (RAM) chips residing on a Dual-Inline Memory Module (DIMM);
a plurality of termination resistors connected between a fixed voltage and respective ones of said transmission lines to terminate said signal lines; and
a plurality of capacitors connected in series with said termination resistors such that each transmission line is AC-coupled to its termination voltage;
each of said output buffers arranged to provide an output signal to drive a respective one of said transmission lines, said output signal transitioning between ‘low’ and ‘high’ states to convey data bits via said transmission line, each output buffer comprising at least two drive circuits, said at least two drive circuits comprising:
a first drive circuit having an input which is coupled to an input signal and which provides a first drive signal which transitions between ‘low’ and ‘high’ states in response to respective transitions of said input signal; and
a second drive circuit having an input which is coupled to said input signal and which provides a second drive signal which transitions between ‘low’ and ‘high’ states in response to respective transitions of said input signal, said buffer arranged such that, in response to a given input signal transition, said second drive signal transitions a predetermined amount of time after said first drive signal, said first and second drive signals summed together to provide said buffer's output signal;
said first and second drive circuits arranged such that, during output signal transitions of at least one polarity, said output signal has a first slew rate prior to the transition of said second drive signal, and a second slew rate during the transition of said second drive signal, said first slew rate being less than said second slew rate.
